(19) United States
(12) Patent Application Publication
(10) Pub. No.: US 2003/0062594 A1
(43) Pub. Date: Apr. 3, 2003

(54) Anti-fuse structure with low on-state resistance and low off-state leakage

(76) Inventor: Chin-Yang Chen, Chi-Lung City (TW)

Correspondence Address: NAIPO (NORTH AMERICA INTERNATIONAL PATENT OFFICE), P.O. BOX 506, MERRIFIELD, VA, 22116, US

(21) Appl. No.: 09/682,628

(22) Filed: Oct. 1, 2001

(51) Int. Cl. H01L 29/00

(52) U.S. Cl. 257/530

(57) ABSTRACT

An anti-fuse structure is set on an isolation layer positioned on a substrate. The anti-fuse structure includes a silicon conductive layer positioned in the isolation layer, a dielectric layer positioned on the top surface of the silicon conductive layer, and a metal conductive layer positioned on the surface of the isolation layer and covering the dielectric layer.

### BACKGROUND OF INVENTION

1. Field of the Invention

The present invention provides an anti-fuse structure with low on-state resistance and low off-state leakage.

2. Description of the Prior Art

In the integrated circuit (IC) field, programmable link, such as fuses and anti-fuses, is widely applied to productions of programmable read only memory (PROM) and field programmable gate array (FPGA). To reduce the costs of research and fabrication, metal wires with a programmable link thereon are usually connected to all transistors in a memory array of a semiconductor wafer. After the fabrication of the semiconductor wafer is completed, data input can be performed from outside.

Take the fuse as an example, if a voltage higher than a specific value is supplied to the connection line to burn out the programmable link (fuse), the fuse becomes open-circuit. It is called off-state of the fuse and data “1” is stored in the PROM cell.

Conversely, an un-burned fuse means that the connection line of the transistor exists and remains conductive, which is called on-state of the fuse and data “0” is stored in the PROM cell. The above-mentioned process of supplying the high voltage to burn the fuse is called a programming process. Following the programming processes, programmed fuses with off-state and un-programmed fuses with on-state form a digital bit pattern to store data.

As for the anti-fuse, it is a device of operation rules against that of the fuse. When a voltage lower than a specific value is supplied to the anti-fuse, the anti-fuse becomes non-conductive and is called in an off-state. But when a programming voltage higher than a specific value is supplied to the anti-fuse, the anti-fuse becomes conductive and is called in an on-state. In comparison with the fuse, lower programming currents and fewer programmed circuits are required for the anti-fuse. In addition, the anti-fuse occupies less space and is utilized to develop high integration for the semiconductor processes. Therefore, the anti-fuse gradually substitutes for the fuse.

Typically, the anti-fuse comprises two electrodes and a dielectric layer positioned between the two electrodes. The dielectric layer is formed of a single dielectric material or multiple dielectric materials. Introductions to the anti-fuse structures are disclosure in the American patents. According to the materials forming the electrodes, the anti-fuse structures are mainly divided into two groups. The first group is silicon-silicon anti-fuse, using silicon to form the electrodes, such as disclosed in U.S. Pat. Nos. 4,543,594, 6,103,555. The second group is metal-metal anti-fuse, using metal to form the electrodes, such as disclosed in U.S. Pat. Nos. 5,196,724, 5,793,094, 6,150,705.

Please refer to FIG. 1 of a schematic diagram of a silicon-silicon anti-fuse 11 on a semiconductor wafer 10. As shown in FIG. 1, the semiconductor wafer 10 comprises a silicon substrate 12. The silicon-silicon anti-fuse 11 uses a diffusion area of the silicon substrate 12 as a bottom electrode 13. The silicon-silicon anti-fuse 11 further comprises an inter-dielectric layer 14 positioned on the surface of the silicon substrate 12, a contact hole 16 positioned in the inter-dielectric layer 14 down to the surface of the bottom electrode 13. An ONO dielectric layer 24, composing of a bottom oxide layer 18, a silicon nitride layer 20 and a top oxide layer 22, covers the surfaces of the contact hole 16 and inter-dielectric layer 14. A polysilicon layer 26, functioning as a top electrode, covers the ONO dielectric layer 24 and fills the contact holes 16.

Before programming, as shown in this structure, the silicon-silicon anti-fuse 11 has a capacitor-like structure during the off-state. Because this anti-fuse 11 uses the diffusion area of the silicon substrate 12 as the bottom electrode 13, a high-temperature oxidation or a high-temperature deposition process can be used to form the dielectric layer 24 of good deposition quality. When a normal operation voltage (about 5 volts) is supplied to this anti-fuse structure 11, the current leakage problems of the anti-fuse structure 11 can be well controlled.

However, when a programming voltage (about 18-30 volts) is supplied to the anti-fuse structure 11, high current density leads to high local energy dissipation.

Therefore, the ONO dielectric layer 24 between the bottom electrode 13 and the polysilicon layer 26 is broken down to form a permanent silicon link. The programming process drives the dopant atoms in the bottom electrode 13 and the polysilicon layer 26 to move to the link, therefore, the resistance of the link is determined by the dopant atoms distribution. Normally, when the programming voltage is supplied, the on-state resistance of the link is about 300-500 W. In addition, since the resistance of the silicon is higher than metal, the silicon-silicon anti-fuse has higher on-state resistance than the metal-metal anti-fuse.

Please refer to FIG. 2 of a schematic diagram of a metal-metal anti-fuse structure 31. As shown in FIG. 2, a semiconductor wafer 30 comprises a silicon substrate 32, a silicon oxide layer, functioning as an isolation layer 34, covers the silicon substrate 32. The metal-metal anti-fuse structure 31 is set on the isolation layer 34, comprising a first metal layer 36, an inter-dielectric layer 38, a dielectric layer 42 and a second metal layer 44. The first metal layer 36 covers the isolation layer 34, functioning as a bottom electrode of the anti-fuse. The inter-dielectric layer 38 covers the first metal layer 36. A contact hole 40 is formed in the inter-dielectric layer 38 down to the surface of the first metal layer 36. The dielectric layer 42 formed by amorphous silicon or silicon dioxide covers the bottom and sidewalls of the contact hole 40 and the surface of the inter-dielectric layer 38. The second metal layer 44 covers the dielectric layer 42, functioning as a top electrode of the anti-fuse.

Before programming, as shown in this anti-fuse structure, the metal-metal anti-Page fuse 31 has a capacitor-like structure in the off-state. Because the anti-fuse 31 uses metal materials as the bottom electrode 36, the dielectric layer 42 must be formed by a deposition method with a temperature lower than 400° C. Therefore, the quality of the dielectric layer 42 of this anti-fuse 31 is poor. Consequently, when a normal operation voltage (about 5 Volts) is applied to the anti-fuse 31, high leakage currents of the anti-fuse 31 are induced and seriously affect a control of the programming voltage and cause storage time degradation of a MOS device. And when a programming voltage is supplied to the anti-fuse structure 31, the dielectric layer 42 between the first metal layer 36 and the second metal layer 44 is broken down to form a permanent metal link, such as W, Ti, or TiW. Normally, when the programming voltage is supplied, the resistance of the metal link is about 80-100 W. The resistance of the metal link is much lower than that of the silicon-silicon anti-fuse structure 11.

Therefore, after programming, this anti-fuse 31 has lower on-state resistance than the anti-fuse 11.

Above all, silicon-silicon anti-fuse has lower off-state leakage before programming, but has higher on-state resistance after programming. The metal-metal anti-fuse has higher off-state leakage but lower on-state resistance. Therefore, both of these two types of anti-fuses have their disadvantages and thus can't be well applied to semiconductor processes.

### SUMMARY OF INVENTION

It is therefore a primary objective of the present invention to provide an anti-fuse structure, to solve the above-mentioned problems.

In accordance with the claimed invention, the anti-fuse structure is set on an isolation layer positioned on a substrate. The anti-fuse structure comprises a silicon conductive layer positioned in the isolation layer and protruding the surface of the isolation layer, a dielectric layer positioned on the top surface of the silicon conductive layer, and a metal conductive layer positioned on the surface of the isolation layer and covering the dielectric layer.

It is an advantage of the present invention that silicon is used to form a bottom electrode, thus the dielectric layer with high quality can be formed on the surface of the silicon by high-temperature treatment. Therefore, the high current leakage problems of the metal-metal anti-fuse as in the prior art are avoided according to the present invention. In addition, the present invention uses metal to form a top electrode, so that high resistance problems of the silicon-silicon anti-fuse as in the prior art are avoided.

These and other objectives of the present invention will no doubt become obvious to those of ordinary skill in the art after reading the following detailed description of the preferred embodiment, which is illustrated in the various figures and drawings.

### BRIEF DESCRIPTION OF DRAWINGS

FIG. 1 and FIG. 2 are schematic diagrams of two major anti-fuse structures according to the prior art.

FIG. 3 to FIG. 6 are schematic diagrams of several embodiments of an anti-fuse structure according to the present invention.

FIG. 7 to FIG. 11 are schematic diagrams of fabricating the anti-fuse structure shown in FIG. 3 according to the present invention.

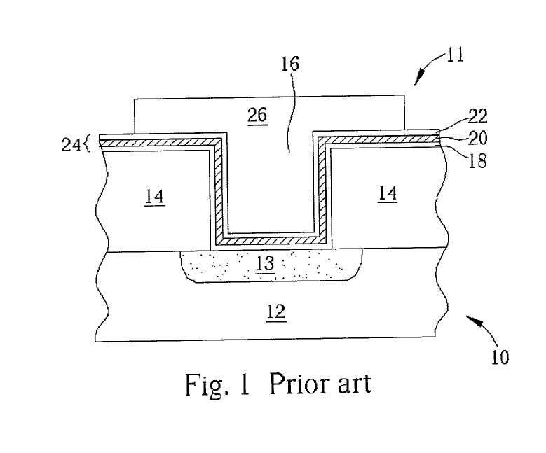

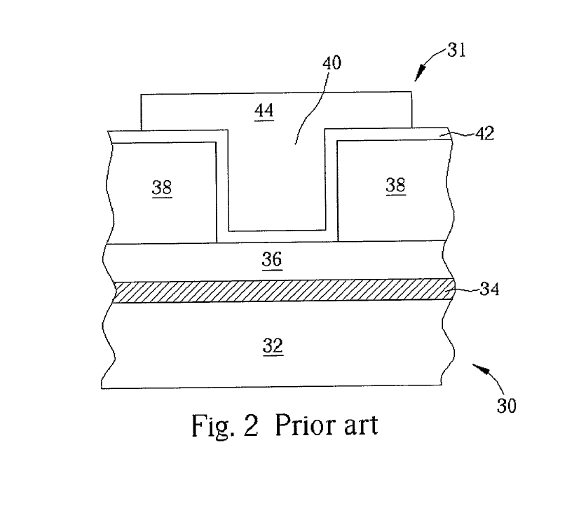

### DETAILED DESCRIPTION

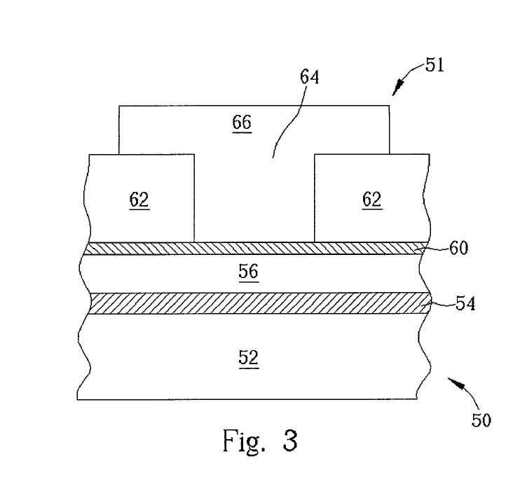

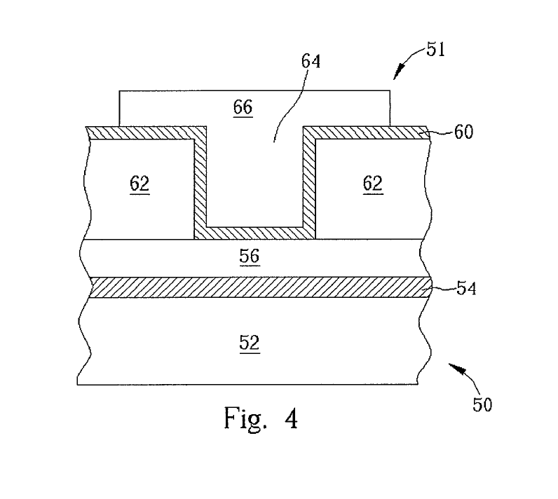

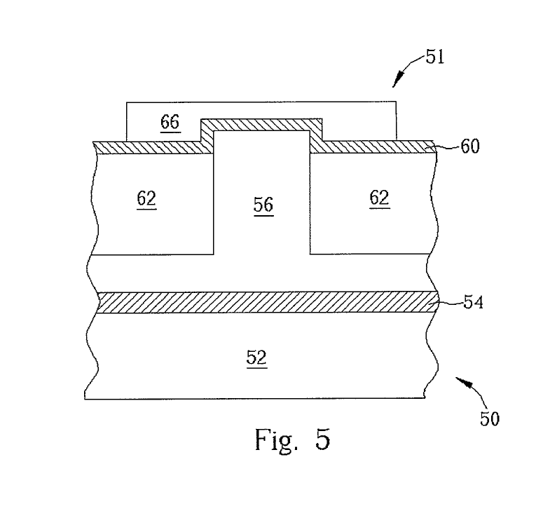

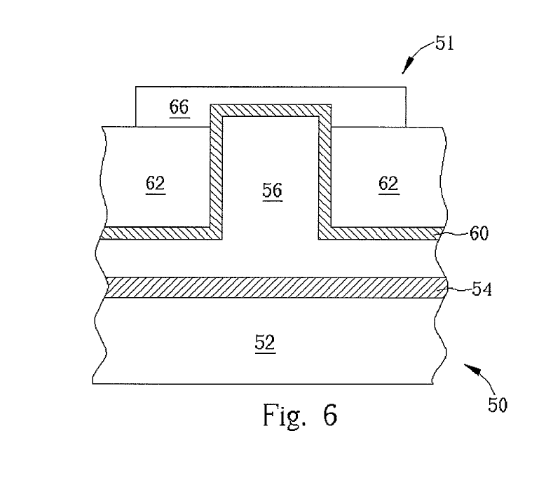

Please refer to FIG. 3 to FIG. 6 of schematic diagrams of several embodiments of an anti-fuse structure according the present invention. A semiconductor wafer 50 comprises a silicon substrate 52. An isolation layer 54 is positioned on the silicon substrate 52 and an anti-fuse structure 51 is set on the isolation layer 54. The anti-fuse structure 51 comprises a silicon conductive layer 56 used as a bottom electrode of the anti-fuse 51, a dielectric layer 60 set on the silicon conductive layer 56, an inter dielectric layer 62 set either on the dielectric layer 60 (FIG. 3 and FIG. 6) or between the dielectric layer 60 and the silicon conductive layer 56 (FIG. 4 and FIG. 5), and a metal conductive layer 66 covering the surfaces of the inter dielectric layer 62 and dielectric layer 60, the metal conductive layer 66 functioning as a top electrode of the anti-fuse 51. In addition, the anti-fuse structure 51 can also uses a diffusion area of the silicon substrate 52 as the bottom electrode, and in this case, the isolation layer 54 and the silicon conductive layer 56 shown in FIG. 3 and FIG. 4 can be omitted from the structure of the anti-fuse

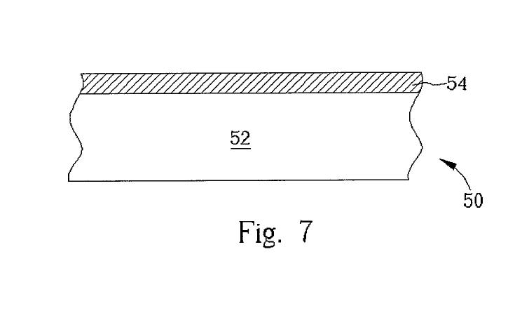

Please refer to FIG. 7 to FIG. 11 of schematic diagrams of fabricating the anti-fuse structure 51 shown in FIG. 3. As shown in FIG. 7, the semiconductor wafer 50 comprises the silicon substrate 52 and an isolation layer 54 composed of silicon dioxide or other isolation materials is set on the silicon substrate 52. Wherein, the silicon substrate 52 can also be replaced with a substrate of silicon on insulator (SOI).

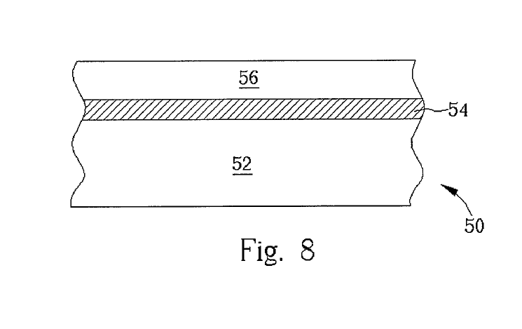

As shown in FIG. 8, a chemical vapor deposition (CVD) is used to form a silicon conductive layer 56 on the isolation layer 54 with a thickness of 5000-15000 angstroms. The silicon conductive layer 56 is used as the bottom electrode of the anti-fuse 51. Wherein, the silicon conductive layer 56 is a doped polysilicon layer, a doped amorphous silicon layer or a silicide layer. In addition, according to the present invention, a hemi-spherical grain (HSG) process and an implantation process of phosphor (P), boron (B) or arsenic (As) atoms are performed to the surface of silicon conductive layer 56. Therefore, a plurality of HSG structures are formed on the surface of silicon conductive layer 56. The HSG structures are used to enhance a local electric field, thereby reducing an operation voltage of the anti-fuse structure 51.

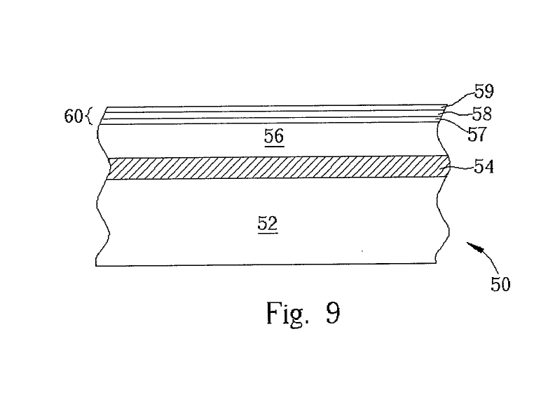

As shown in FIG. 9, a high-temperature oxidation process and a high-temperature deposition process are then used to form the dielectric layer 60, such as an ONO layer, on the silicon conductive layer 56. The ONO dielectric layer 60 is composed of a bottom oxide layer 57, a silicon nitride layer 58 and a top oxide layer 59. To form the ONO dielectric layer 60, a native oxide layer with a thickness of 10-50 angstroms is first formed on the surface of the silicon conductive layer 56 and functions as the bottom oxide layer 57. Following this, a low-pressure chemical vapor deposition (LPCVD) process is performed by introducing dichlorosiliane (SiH₂Cl₂) and ammonia (NH₃) into a deposition chamber at a temperature of 700-800° C. and the silicon nitride layer 58 with a thickness of 45 angstroms is thus formed on the surface of the bottom oxide layer 57. Finally, the semiconductor wafer 50 is put in an oxygen-containing environment with a temperature of 800° C. for a period of approximately 30 minutes, and as a result, the structure of the silicon nitride layer 58 is repaired and a silicon oxy-nitride layer with a thickness of 40-80 angstroms is formed on the surface of the silicon nitride layer 58, functioning as the top oxide layer 59. However, the dielectric layer 60 is not limited to the ONO dielectric layer only, and other dielectric layer such as a single dielectric layer or a stacked dielectric layer composed of at least two dielectric materials are also applicable in the present invention.

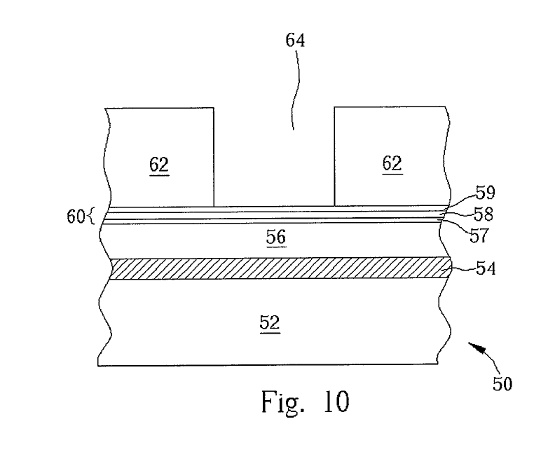

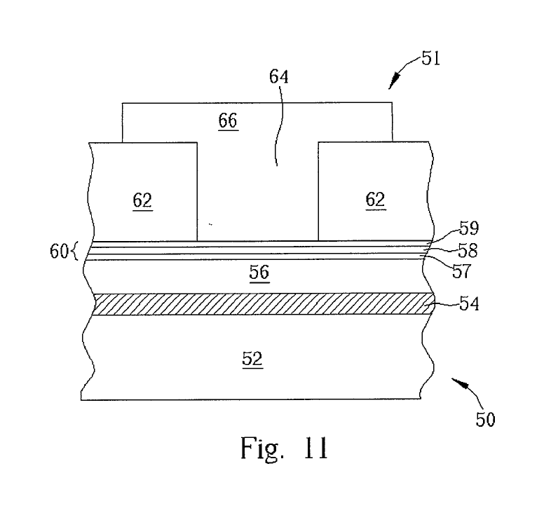

As shown in FIG. 10, a chemical vapor deposition is then used to form a silicon oxide layer with a thickness of 2000-3000 angstroms on the surface of the ONO dielectric layer 60, the silicon oxide layer functioning as the inter-dielectric layer 62. A photo-etching process (PEP) is then used to define a position of a contact hole 64 in the inter-dielectric layer 62 down to the surface of the ONO dielectric layer 60. Finally, as shown in FIG. 11, a metal sputtering method is used to form the metal conductive layer 66 with a thickness of 5000-15000 angstroms above the inter-dielectric layer 62 and filling the contact hole 64 with the metal conductive layer 66. The metal conductive layer 66 is composed of Ti, TiW or W and functions as the top electrode of the anti-fuse structure 51 according to the present invention.

Because silicon is used to form the bottom electrode in the present invention, the high-temperature oxidation and deposition process can be performed to form the dielectric layer with better dielectric characteristics on the surface of the silicon substrate. Therefore, the quality of the dielectric layer of the anti-fuse is enhanced and the off-state leakage of the anti-fuse is reduced. In addition, the present invention uses metal to form the top electrode, so the on-state resistance of the anti-fuse is reduced. Consequently, the anti-fuse structure of the present invention simultaneously has the advantages of low off-state leakage and low on-state resistance.

In contrast to the two types of the anti-fuses of the prior art, the present invention uses silicon to form the bottom electrode, so the high-temperature treatment is applicable in the fabrication of the anti-fuse. Therefore, the dielectric layer with better quality is formed on the surface of the silicon material to avoid off-state leakage problems of the prior art metal-metal anti-fuse. In addition, the present invention uses metal to form the top electrode to reduce on-state resistance, and thus avoids problems of high on-state resistance of the prior art silicon-silicon anti-fuse.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. An anti-fuse structure having low on-state resistance and low off-state leakage, the anti-fuse structure being set on an isolation layer of a substrate, the structure comprising:
a silicon conductive layer set in the isolation layer, the silicon conductive layer protruding the surface of the isolation layer;
a dielectric layer set on the top surface of the silicon conductive layer; and
a metal conductive layer set on the surface of the isolation layer and covering the surface of the dielectric layer.

2. The structure of claim 1 wherein the substrate is a semiconductor wafer.

3. The structure of claim 1 wherein the substrate comprises a silicon-on-insulator (SOI) substrate.

4. The structure of claim 1 wherein the silicon conductive layer comprises doped polysilicon.

5. The structure of claim 1 wherein the silicon conductive layer comprises doped amorphous silicon (α-Si).

6. The structure of claim 1 wherein the silicon conductive layer comprises doped polysilicon, doped amorphous silicon or silicide.

7. The structure of claim 1 wherein the silicon conductive layer further comprises a plurality of hemi-spherical grain (HSG) structures to enhance a local electric field so as to reduce an operation voltage of the anti-fuse structure.

8. The structure of claim 1 wherein the dielectric layer is a stacked dielectric layer stacked by at least two dielectric materials.

9. The structure of claim 8 wherein the dielectric layer is an ONO layer composed of a bottom oxide layer, a silicon nitride layer and a top oxide layer.

10. The structure of claim 1 wherein a fabrication method of the dielectric layer comprises a high temperature treatment to enhance the quality of the dielectric layer so as to reduce the off-state leakage of the anti-fuse structure.

11. An anti-fuse structure, the structure comprising:
a silicon conductive layer;
a dielectric layer set on the surface of the silicon conductive layer; and
a metal conductive layer covering the surface of the dielectric layer.

12. The structure of claim 11 wherein the anti-fuse structure is set in an isolation layer positioned on a semiconductor wafer.

13. The structure of claim 11 wherein the anti-fuse structure is set in an isolation layer positioned on a silicon-on-insulator (SOI) substrate.

14. The structure of claim 11 wherein the silicon conductive layer comprises doped polysilicon.

15. The structure of claim 11 wherein the silicon conductive layer comprises doped amorphous silicon.

16. The structure of claim 11 wherein the silicon conductive layer comprises doped polysilicon, doped amorphous silicon or silicide.

17. The structure of claim 11 wherein a surface of the silicon conductive layer further comprises a plurality of hemi-spherical grain (HSG) structures to enhance a local electric field so as to reduce an operation voltage of the anti-fuse structure.

18. The structure of claim 11 wherein the dielectric layer is a stacked dielectric layer stacked by a plurality of dielectric materials.

19. The structure of claim 18 wherein the dielectric layer is an ONO layer.

20. The structure of claim 19 wherein a fabrication method of the dielectric layer comprises a high temperature treatment to enhance the quality of the dielectric layer so as to reduce the off-state leakage of the anti-fuse structure.
